(19) United States
(12) Patent Application Publication
(10) Pub. No.: US 2009/0040728 A1
(43) Pub. Date: Feb. 12, 2009

(54) Fixing Structure and Heat Dissipation Device

(75) Inventors: Chi-Chuan Chen, Taipei (TW); Ming-Hsiu Wu, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/173,097

(22) Filed: Jul. 15, 2008

(30) Foreign Application Priority Data
Aug. 10, 2007 (TW) 96129733

(51) Int. Cl. H05K 7/20

(52) U.S. Cl. 361/709

(57) ABSTRACT

A fixing structure includes a back plate, a fixing plate, a first elastic element, a second elastic element and a fastener. The back plate has a positioning pillar thereon. The fixing plate presses a heat dissipation element to allow the heat dissipation element to contact a chip above the back plate. Both the first elastic element and the second elastic element are connected to the fixing plate. The fastener fastens the first elastic element and the second elastic element to the positioning pillar or just fastens the first elastic element to the positioning pillar to allow the second elastic element to be suspended. Furthermore, a heat dissipation device employing the fastening structure is also disclosed.

### RELATED APPLICATIONS

This application claims priority to Taiwan Application Serial Number 96129733, filed Aug. 10, 2007, which is herein incorporated by reference.

### BACKGROUND OF THE INVENTION

1. Field of the Invention

The invention relates to a fixing structure and, more particularly, to a fixing structure applied to a heat dissipation element and a heat dissipation device thereof.

2. Description of the Related Art

To allow the computer to process a large of data more rapidly, the computer manufacturer should try to increase the processing speed of the chip in the computer. However, with the increase of the processing speed of the chip, the heat generated by the chip in running is more and more. Therefore, a good heat dissipation device for dissipating heat is needed.

Most of the conventional heat dissipation devices contact the chip directly, and the heat generated by the chip is conducted to the heat dissipation devices. However, once the heat dissipation device does not contact the chip very well, the heat conducting efficiency greatly decreases, and then the heat generated by the chip cannot be dissipated by the heat dissipation device successfully.

### BRIEF SUMMARY OF THE INVENTION

The invention provides a fixing structure for fixing a heat dissipation element to allow the heat dissipating element to contact the chip.

According to one embodiment of the invention, a fixing structure including a back plate, a fixing plate, a first elastic element, a second elastic element and a fastener is provided. The back plate has a positioning pillar thereon. The fixing plate presses the heat dissipation element to allow the heat dissipation element to contact a chip above the back plate. The first elastic element and the second elastic element are connected to the fixing plate. A user may use a fastener to fasten the first elastic element and the second elastic element to the positioning pillar or only to fasten the first elastic element to the positioning pillar and allow the second elastic element to be suspended.

The invention also provides a heat dissipation device utilizing the fixing structure.

According to another embodiment of the invention, a heat dissipation device includes a back plate, a temperature homogenizing element, a heat pipe, a fixing plate, a first elastic element, a second elastic element and a fastener. The back plate has a positioning pillar thereon. The temperature homogenizing element contacts a chip above the back plate. The heat pipe contacts the temperature homogenizing element. The fixing plate has a recess for holding the heat pipe. The first elastic element and the second elastic element are connected to the fixing plate. A user may use a fastener to fasten the first elastic element and the second elastic element to the positioning pillar or only to fasten the first elastic element to the positioning pillar and allow the second elastic element to be suspended.

To sum up, in the embodiment of the invention, the position of the heat dissipation element can be fixed. In addition, when the area of the chip is less, and the stress that the chip can bear is less, a user may choose only to fasten the first elastic element to the positioning pillar. Thus, the fixing plate presses the heat dissipation element with a less force to avoid damaging the chip. On the other hand, when the area of the chip is larger, and the stress that the chip can bear is larger, the user may choose to fasten the first elastic element and the second elastic element to the positioning pillar together. Thus, the fixing plate presses the heat dissipation element with a larger force to allow the chip to contact the heat dissipation element closely.

According to one embodiment of the invention, just one fixing structure or heat dissipation device may be applied to various chips which need different fixing stress. For manufacturers manufacturing a large number of electronic elements such as electronic cards, they do not need to design different fixing structures for different chips. Therefore, time and cost is saved.

These and other features, aspects, and advantages of the present invention will become better understood with regard to the following description, appended claims, and accompanying drawings.

### BRIEF DESCRIPTION OF THE DRAWINGS

FIG. 1A to 1C are longitudinal section diagrams showing a fixing structure in various states according to one embodiment of the invention;

FIG. 2 is a three-dimensional diagram showing the fixing plate, the first elastic element and the second elastic element shown in FIG. 1; and

FIG. 3 is a top view showing a fixing plate, a first elastic element and a second elastic element according to another embodiment of the invention.

### DETAILED DESCRIPTION OF THE EMBODIMENTS

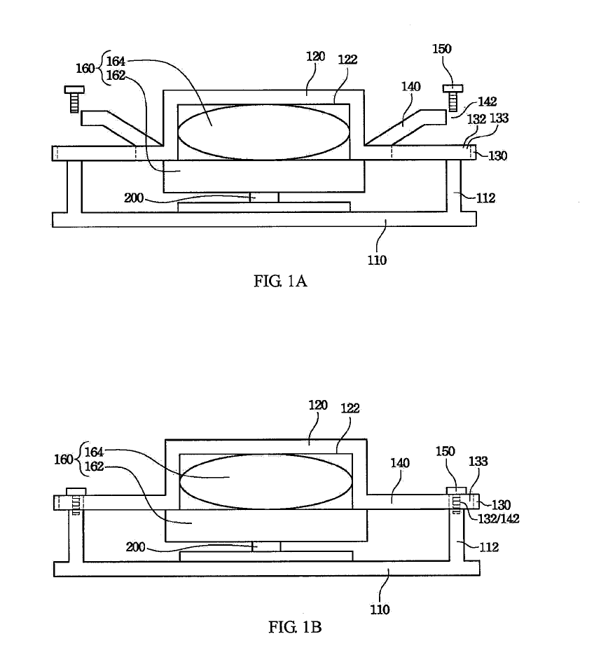

FIG. 1A to 1C are longitudinal section diagrams showing a fixing structure in various states according to one embodiment of the invention. A fixing structure includes a back plate 110, a fixing plate 120, a first elastic element 130, a second elastic element 140 and a fastener 150. The back plate 110 has a positioning pillar 112 thereon. The fixing plate 120 presses the heat dissipation clement 160 to allow the heat dissipation element 160 to contact a chip 200 above the back plate 110. The first elastic element 130 and the second elastic element 140 are connected to the fixing plate 120. A user may use the fastener 150 to fasten the first elastic element 130 and the second elastic element 140 to the positioning pillar 112 together (as shown in FIG. 1B), or the user may only fasten the first elastic element 130 to the positioning pillar 112 and allow the second elastic element 140 to be suspended (as shown in FIG. 1C). The definition of the “suspended” is that “the second elastic element 140 is not connected to or contacts any element of the fixing structure except one end of the fixing plate 120”.

In addition, the embodiment also discloses a heat dissipation device. The heat dissipation element 160 may includes a temperature homogenizing element 162 and the heat pipe 164. The temperature homogenizing element 162 contacts the chip 200 above the back plate 110. The heat pipe 164 contacts the temperature homogenizing element 162, and it is held in the recess 122 of the fixing plate 120. In detail, the fixing plate 120 may be riveted to the temperature homogenizing element 162. The heat pipe 164 is between the temperature homogenizing element 162 and the fixing plate 120. In addition, the material of the temperature homogenizing element 162 is not limited and is preferred to be copper.

If the pressing force that the fixing plate 120 applies to the heat dissipation element 160 is larger, the contact between the heat dissipation element 160 and the chip 200 is better. However, the stress born by the chip 200 becomes larger. Nowadays, the chip on the market becomes more and more diversified, and size of the chip and stress that the chip can bear are different. Therefore, according to the kind of the chip, a user may choose to fasten the first elastic element 130 and the second elastic element 140 to the positioning pillar together The user also may only fasten the first elastic element 130 to the positioning pillar 112 to allow the heat dissipation element 160 to contact the chip 200 by the enough pressing force of the fixing plate 120 and avoid damaging the pins of the chip 200.

When the area of the chip 200 is less, and the stress that the chip 200 can bear is less, the user may choose only to fasten the first elastic element 130 to the positioning pillar 112 (as shown in FIG. 1C). It allows the pressing force that the fixing plate 120 applies to the heat dissipation element 160 to become less to avoid damaging the chip 200. On the other hand, when the area of the chip 200 is larger, and the stress that the chip 200 can bear is larger, the user may choose to fasten the first elastic element 130 and the second elastic element 140 to the positioning pillar 112 (as shown in FIG. 1B). Thus, the fixing plate 120 presses the heat dissipation element 160 with a larger force to allow the chip 200 to contact the heat dissipation element 160 closely.

In the embodiment, the fastener 150 may be a screw. When the fastener 150 is a screw, the first elastic element 130 may have a screw hole 132 to allow the screw to fasten the first elastic element 130 to the positioning pillar 112. Similarly, the second elastic element 140 also may have a screw hole 142 to allow the screw to fasten the second elastic element 140 to the positioning pillar 112.

As shown in FIG. 1A, when the first elastic element 130 and the second elastic element 140 are not fastened to the positioning pillar 112, a height difference is between the screw hole 132 of the first elastic element 130 and the screw hole 142 of the second elastic element 140. In this way, when the fastener 150 fastens the first elastic element 130 and the second elastic element 140 to the positioning pillar 112, the first elastic element 130 and the second elastic element 140 have different compress strokes. That is, the second elastic element 140 can further increase the potential energy provided by the first elastic element 130 to allow the pressing force of the fixing plate 120 to increase. Thus, the chip 200 and the heat dissipation element 160 contact each other closely.

In addition, the screw hole 132 of the first elastic element 130 may have a margin 133 along the direction of being away from the fixing plate 120. In this way, when an assembler wants to change the state of the fixing structure shown in FIG. 1B to the state shown in FIG. 1C, he only needs to separate the fastener 150 from the positioning pillar 112 and move the fastener 150 outward in the screw hole 132. Thus, the second elastic element 140 is loosed and suspended. Then, he moves the fastener 150 inward to be above the positioning pillar 112, and he fastens the first elastic element 130 to the positioning pillar 112.

When the assembler wants to change the state of the fixing structure shown in FIG. 1C to the state shown in FIG. 1B, he only needs to loose the fastener 150 from the positioning pillar 112 and move the fastener 150 outward in the screw hole 132. Then, he presses the second elastic element 140 and moves the fastener 150 inward to be above the positioning pillar 112, and he fastens the first elastic element 130 and the second elastic element 140 to the positioning pillar 112 together.

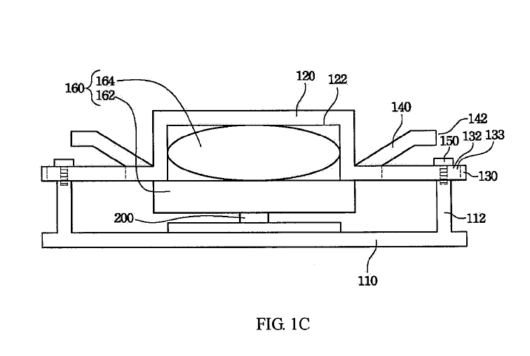

The “screw hole” means not only the screw hole that the first elastic element or the second elastic element actually has, it also means any elements or structures suitable for being assembled with screws as long as the screws can fasten the first elastic element and/or second elastic element to the positioning pillar. For example, the fastener 150 (such as a screw) shown in FIG. 1A can fasten the edge of the second elastic element 140 directly instead of passing through the second elastic element 140. Therefore, the screw hole 142 may be regarded as the external room of the second elastic element 140 in the embodiment. The surface of the second elastic element 140 and the surface where the second elastic member 140 contacts the fastener 150 may be designed to be arc-shaped (as shown in FIG. 2) to allow them to contact each other closely. The above does not limit the invention, and the people having ordinary skills can choose the implementing manner of the “screw hole” elastically.

FIG. 2 is a three-dimensional diagram showing the fixing plate 120, the first elastic element 130 and the second elastic element 140 shown in FIG. 1. Besides adjusting the compression strokes of the first elastic element 130 and the second elastic element 140, a user also may choose to change the section area of the first elastic element 130 and the second elastic element 140 to adjust the pressing force of the fixing plate 120. For example, the section area of the second elastic element 140 shown in FIG. 2 is different from the section area of the first elastic element 130.

In addition, the fixing plate 120, the first elastic element 130 and the second elastic element 140 shown in FIG. 2 may be integrally formed. In detail, the material of the fixing plate 120, the first elastic element 130 and the second elastic element 140 is not limited, and it preferably includes metal. Then, the fixing plate 120, the first elastic element 130 and the second elastic element 140 are manufactured in a simple metal processing manner (such as the metal punching) via the original elasticity of the metal. The above material is an example and is not used for limiting the invention. The material of the first elastic element and the second elastic element may include other flexible material People having ordinary skills in the art may choose the implementing manner of the first elastic element and the second elastic element elastically according to the actual need.

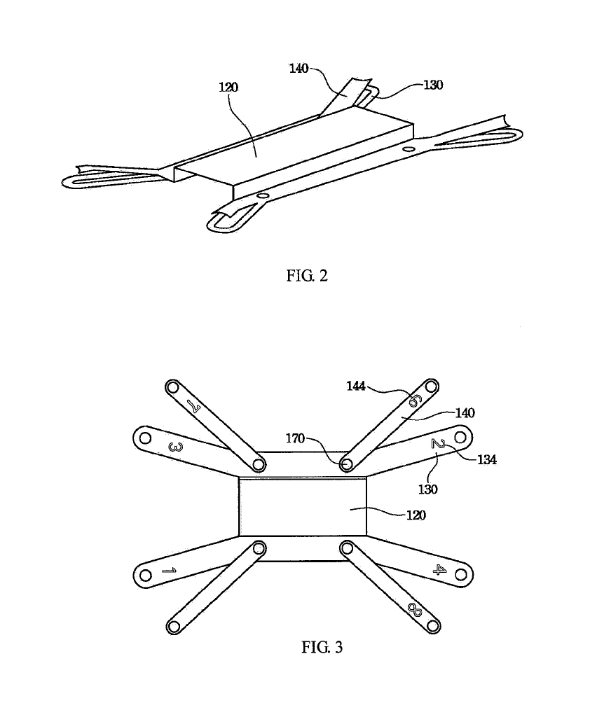

FIG. 3 is a top view showing a fixing plate 120, a first elastic element 130 and the second elastic element 140 according to another embodiment of the invention. In the embodiment, the fixing plate 120 and the first elastic element 130 may be integrally formed. The second elastic element 140 may be riveted to the fixing plate 120 to retain the rotating freedom of the second elastic element 140 relative to the fixing plate 120. In detail, the fixing device of the embodiment further may include a rivet 170 to rivet the second elastic element 140 to the fixing plate 120. The rivet 170 may selectively rivet the second elastic element 140 and the fixing plate 120 or further rivet the temperature homogenizing element (the temperature homogenizing element 162 shown in FIG. 1A).

As shown in FIG. 3, the first elastic element 130 and the second elastic element 140 of the embodiment may have marks 134 and 144 to prompt an assembler that when both the first elastic element 130 and the second elastic element 140 should be fastened and when just the first elastic element 130 needs to be fastened according to the different kind of the chip. The first elastic element 130 and the second elastic element 140 do not need both of the marks 134 and 144. The first elastic element 130 may have the mark 134, or the second elastic element 140 may have the mark 144. People having ordinary skills may choose the implementing manner of the mark according to the need elastically.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A fixing structure applied to a heat dissipation element, the fixing structure comprising:
a back plate having at least a positioning pillar thereon;
a fixing plate pressing the heat dissipation element to allow the heat dissipation element to contact a chip above the back plate;
at least a first elastic element connected to the fixing plate;
at least a second elastic element connected to the fixing plate; and
at least a fastener for fastening the first elastic element and the second elastic element to the positioning pillar or only fastening the first elastic element to the positioning pillar to allow the second elastic element to be suspended.

2. The fixing structure according to claim 1, wherein when the fastener fastens the first elastic element and the second elastic element to the positioning pillar together, the first elastic element and the second elastic element have different compression strokes.

3. The fixing structure according to claim 1, wherein the fastener is a screw.

4. The fixing structure according to claim 3, wherein both the first elastic element and the second elastic element have screw holes.

5. The fixing structure according to claim 4, wherein the screw hole of the first elastic element has a margin along the direction of being away from the fixing plate.

6. The fixing structure according to claim 4, wherein when the first elastic element and the second elastic element are not fastened to the positioning pillar, a height difference is between the screw hole of the first elastic element and the screw hole of the second elastic element.

7. The fixing structure according to claim 1, wherein the section area of the first elastic element is different from the section area of the second elastic element.

8. The fixing structure according to claim 1, wherein the first elastic element, the second elastic element and the fixing plate are integrally formed.

9. The fixing structure according to claim 1, wherein the first elastic element and the fixing plate are integrally formed.

10. The fixing structure according to claim 1, wherein the second elastic element is riveted to the fixing plate.

11. A heat dissipation device comprising:
a back plate having at least a positioning pillar thereon;
a temperature homogenizing element contacting a chip above the back plate;
a heat pipe contacting the temperature homogenizing element;
a fixing plate having a recess for holding the heat pipe;
at least a first elastic element connected to the fixing plate;
at least a second elastic element connected to the fixing plate; and
at least a fastener for fastening the first elastic element and the second elastic element to the positioning pillar or only fastening the first elastic element to the positioning pillar to allow the second elastic element to be suspended.

12. The heat dissipation device according to claim 11, wherein when the fastener fastens the first elastic element and the second elastic element to the positioning pillar together, the first elastic element and the second elastic element have different compression strokes.

13. The heat dissipation device according to claim 11, wherein the fastener is a screw.

14. The heat dissipation device according to claim 13, wherein both the first elastic element and the second elastic element have screw holes.

15. The heat dissipation device according to claim 14, wherein the screw hole of the first elastic element has a margin along the direction of being away from the fixing plate.

16. The heat dissipation device according to claim 14, wherein when the first elastic element and the second elastic element are not fastened to the positioning pillar, a height difference is between the screw hole of the first elastic element and the screw hole of the second elastic element.

17. The heat dissipation device according to claim 11, wherein the section area of the first elastic element is different from the section area of the second elastic element.

18. The heat dissipation device according to claim 11, wherein the first elastic element, the second elastic element and the fixing plate are integrally formed.

19. The heat dissipation device according to claim 11, wherein the first elastic element and the fixing plate are integrally formed.

20. The heat dissipation device according to claim 11 further comprising a rivet for riveting the second elastic element and the fixing plate.
